(19) United States
(12) Patent Application Publication
(10) Pub. No.: US 2026/0369967 A1
(43) Pub. Date: Nov. 19, 2026

(54) SEMICONDUCTOR LASER ELEMENT

(71) Applicant: HAMAMATSU PHOTONICS K.K., Hamamatsu-shi, Shizuoka (JP)

(72) Inventors: Masahiro HITAKA, Shizuoka (JP); Kazuyoshi HIROSE, Shizuoka (JP); Akio ITO, Shizuoka (JP); Takahiro SUGIYAMA, Shizuoka (JP)

(73) Assignee: HAMAMATSU PHOTONICS K.K., Hamamatsu-shi, Shizuoka (JP)

(21) Appl. No.: 19/133,881

(22) PCT Filed: Jul. 25, 2023
(86) PCT No.: PCT/JP2023/027245

§ 371 Date: May 29, 2025

(30) Foreign Application Priority Data
Dec. 16, 2022 (JP) 2022-207918
Apr. 27, 2023 (JP) 2023-073637

(51) Int. Cl. H01S 5/30; H01S 5/042

(52) U.S. Cl. CPC H01S 5/3077; H01S 5/04256; H01S 5/3054

(57) ABSTRACT

A semiconductor laser device according to one embodiment includes a semiconductor substrate and a semiconductor multilayer structure formed on the semiconductor substrate. The semiconductor multilayer structure includes an active layer, a p-type cladding layer disposed between the semiconductor substrate and the active layer, a non-doped guide layer disposed between the p-type cladding layer and the active layer, an n-type guide layer disposed on a side of the active layer opposite to a side where the non-doped guide layer is located, and an n-type cladding layer disposed on a side of the n-type guide layer opposite to a side where the active layer is located. Zn is doped in the p-type cladding layer. The non-doped guide layer is formed of InAlₓGa₁₋ₓAs (0<x≤1). The thickness of the n-type guide layer is greater than the thickness of the non-doped guide layer.

### TECHNICAL FIELD

The present disclosure relates to a semiconductor laser element.

### BACKGROUND ART

Patent Literature 1 discloses a semiconductor laser device having a structure in which, on an n-type InP substrate, an n-type cladding layer, an n-type guide layer, an active layer, a p-type guide layer, a p-type carrier stop layer, and a p-type cladding layer are stacked in this order. In the above semiconductor laser device, Zn is used as a dopant for the p-type layer. The thickness of the n-type guide layer is set to be the same as that of the p-type guide layer.

### CITATION LIST

### Patent Literature

Patent Literature 1: Japanese Unexamined Patent Publication No. 2014-229742

### SUMMARY OF INVENTION

### Technical Problem

In a semiconductor laser device having the structure described above, there is a problem in that, due to the fact that Zn, which is the dopant for the p-type layer, easily thermally diffuses, it becomes difficult to set the position of the p-n junction interface at a desired position inside or near the active layer as designed, resulting in a decrease in yield. In addition, since the absorption loss of laser light in the p-type layer is greater than that in the n-type layer at the same impurity (doping) concentration, if the waveguide mode of the laser light leaks more into the p-type layer than into the n-type layer, the absorption loss of the laser light increases. The semiconductor laser device disclosed in Patent Literature 1 has room for improvement in view of the above aspects.

Accordingly, one aspect of the present disclosure is to provide a semiconductor laser device capable of improving yield and suppressing loss of laser light.

### Solution to Problem

The present disclosure includes the following semiconductor laser devices [1] to [14].
[1] A semiconductor laser device including:
a semiconductor substrate; and
a semiconductor multilayer structure formed on the semiconductor substrate,
wherein the semiconductor multilayer structure includes:
   an active layer;
   a p-type cladding layer disposed between the semiconductor substrate and the active layer;
   a non-doped guide layer disposed between the p-type cladding layer and the active layer;
   an n-type guide layer disposed on a side of the active layer opposite to a side where the non-doped guide layer is located with respect to the active layer; and
   an n-type cladding layer disposed on a side of the n-type guide layer opposite to a side where the active layer is located with respect to the n-type guide layer,
wherein Zn is doped in the p-type cladding layer,
wherein the non-doped guide layer is formed of InAlₓGa₁₋ₓAs (0<x≤1), and
wherein a thickness of the n-type guide layer in a stacking direction of the semiconductor multilayer structure is greater than a thickness of the non-doped guide layer in the stacking direction.

In the above semiconductor laser device, the non-doped guide layer formed of InAlₓGa₁₋ₓAs can suitably suppress the diffusion of the p-type dopant (Zn) from the p-type cladding layer toward the n-type cladding layer. As a result, it becomes easy to reproducibly set the position of the p-n junction interface at a desired position inside or near the active layer. Furthermore, by making the n-type guide layer thicker than the non-doped guide layer, the waveguide mode of the laser light generated in the active layer can be shifted toward the n-type layers (n-type guide layer, n-type cladding layer), which have a smaller absorption loss for the laser light than the p-type layers (p-type cladding layer). This makes it possible to suitably suppress the absorption loss of the laser light in the p-type layers. Therefore, according to the above semiconductor laser device, it is possible to improve yield and suppress loss of laser light.
[2] The semiconductor laser device according to [1], wherein the semiconductor substrate is p-type.
[3] The semiconductor laser device according to [2],
wherein the semiconductor multilayer structure further includes an n-type contact layer disposed on a side of the n-type cladding layer opposite to a side where the n-type guide layer is located with respect to the n-type cladding layer,
wherein the semiconductor laser device further comprises:
   a first electrode provided on the n-type contact layer, and
   a second electrode provided on a surface of the semiconductor substrate opposite to a side where the semiconductor multilayer structure is located.

According to the above configuration, by using a p-type semiconductor substrate, it is possible to adopt a configuration in which electrodes (the first electrode and the second electrode) for driving the semiconductor laser device are disposed on both sides sandwiching the semiconductor multilayer structure and the semiconductor substrate.
[4] The semiconductor laser device according to claim [1],
wherein the semiconductor substrate is n-type, and
wherein the semiconductor multilayer structure includes a p-type contact layer provided in contact with the p-type cladding layer.

According to the above configuration, in the case where the semiconductor laser device is configured as a surface-emitting laser that emits laser light from a surface of the semiconductor substrate opposite to the side where the semiconductor multilayer structure is located, the absorption loss of the laser light in the semiconductor substrate can be reduced compared to the case where a p-type semiconductor substrate is used, thereby increasing the output of the laser light.
[5] The semiconductor laser device according to [4],
wherein the p-type contact layer is disposed between the semiconductor substrate and the p-type cladding layer,
wherein the semiconductor multilayer structure is provided with a groove extending from a surface of the semiconductor multilayer structure opposite to a side where the semiconductor substrate is located to a first surface of the p-type contact layer opposite to a side where the semiconductor substrate is located, and separating the semiconductor multilayer structure into a first portion and a second portion,
wherein the first portion is provided with an n-type contact layer disposed on a side of the n-type cladding layer opposite to a side where the n-type guide layer is located with respect to the n-type cladding layer,
wherein the semiconductor laser device further comprises:
   a first electrode provided on the n-type contact layer, and
   a second electrode provided so as to extend from a surface of the second portion opposite to a side where the semiconductor substrate is located to the first surface.

According to the above configuration, in the case where an n-type semiconductor substrate is used, the second electrode for driving the semiconductor laser device can be suitably disposed. More specifically, since the first electrode and the second electrode are disposed so as to be spatially separated from each other across the groove on substantially the same plane, the semiconductor laser device can be easily mounted on a wiring substrate by so-called epi-side-down mounting.
[6] The semiconductor laser device according to [4],
wherein the semiconductor multilayer structure further comprises an n-type contact layer disposed on a side of the n-type cladding layer opposite to a side where the n-type guide layer is located with respect to the n-type cladding layer,
wherein the semiconductor multilayer structure is provided with a groove extending from a surface of the semiconductor multilayer structure opposite to a side where the semiconductor substrate is located to a position inside the p-type cladding layer and spaced apart from the semiconductor substrate,
wherein the p-type contact layer is disposed inside the groove,
wherein the semiconductor laser device further comprises:
   a first electrode provided on the n-type contact layer, and
   a second electrode provided on the p-type contact layer.

According to the above configuration, since it is not necessary to form the p-type contact layer between the semiconductor substrate and the p-type cladding layer as in the structure of [5], it is possible to avoid the occurrence of absorption loss of the laser light in the p-type contact layer. As a result, the output of the laser light can be further increased.
[7] The semiconductor laser device according to [5] or [6],
further comprising a third electrode provided on a surface of the semiconductor substrate opposite to a side where the semiconductor multilayer structure is located.

According to the above configuration, by making the first electrode, the second electrode, and the third electrode function as an emitter electrode, a base electrode, and a collector electrode, respectively, the semiconductor laser device can be operated as a high-speed transistor laser.
[8] The semiconductor laser device according to any one of [1] to [7], wherein Si is doped in the n-type guide layer and the n-type cladding layer.

By using Si, which is less likely to thermally diffuse, as the n-type dopant, it is possible to suitably suppress the movement of the p-n junction interface due to diffusion of the n-type dopant toward the p-type layer side. As a result, the position of the p-n junction interface can be adjusted to a desired position with even better reproducibility, thereby further improving yield.
[9] The semiconductor laser device according to any one of [1] to [8], wherein a thickness of the n-type guide layer in the stacking direction is 2 μm or less.

As described above, by making the thickness of the n-type guide layer greater than that of the non-doped guide layer, the waveguide mode can be shifted toward the n-type layer side. However, if the n-type guide layer is made too thick, the waveguide mode may deviate significantly from the active layer, making it difficult to obtain suitable laser oscillation characteristics (the relationship between the injection current and the optical output). In contrast, by limiting the thickness of the n-type guide layer to a certain value or less (2 μm or less) as described above, the occurrence of the above problem can be suppressed.
[10] The semiconductor laser device according to any one of [1] to [9], wherein a thickness of the non-doped guide layer in the stacking direction is 30 nm to 150 nm.

By setting the thickness of the non-doped guide layer to 30 nm or more, the diffusion of Zn from the p-type cladding layer described above can be suitably prevented. Furthermore, by setting the thickness of the non-doped guide layer to 150 nm or less, it is possible to prevent the p-type cladding layer from being too far from the active layer. As a result, it is possible to suppress the p-n junction interface from deviating significantly from the active layer, and thus prevent deterioration of the laser oscillation characteristics.
[11] The semiconductor laser device according to any one of [1] to [10], wherein the n-type guide layer is provided with a fine structure portion having a fine concave-convex structure.

By providing the fine structure portion in the n-type guide layer, which is located on the side opposite to the semiconductor substrate with respect to the active layer and is thicker than the other guide layer (the non-doped guide layer), it is possible to process the fine structure portion with high accuracy and improve the stability of the fine structure portion.
[12] The semiconductor laser device according to [11],
wherein the n-type guide layer includes:
   a base layer having a first refractive index; and
   a plurality of different refractive index regions having a second refractive index different from the first refractive index,
wherein the fine structure portion is constituted by the plurality of different refractive index regions arranged two-dimensionally as viewed from the stacking direction.

According to the above configuration, the semiconductor laser device can function as a photonic crystal surface emitting laser (PCSEL: Photonic Crystal Surface Emitting Laser).
[13] The semiconductor laser device according to [11], wherein the fine structure portion has a diffraction grating distributed along a resonance direction of the active layer perpendicular to the stacking direction.

According to the above configuration, the semiconductor laser device can function as a distributed feedback (DFB) semiconductor laser.
[14] The semiconductor laser device according to any one of [11] to [13], wherein a thickness of the n-type guide layer in the stacking direction is 1.5 times or more a thickness of the non-doped guide layer in the stacking direction.

When the fine structure portion is provided in the n-type guide layer, the waveguide mode shifts toward the p-type layer side compared to the case where the fine structure portion is not provided. By making the thickness of the n-type guide layer 1.5 times or more that of the non-doped guide layer, the degree of such shift can be reduced, and it is possible to suppress the waveguide mode from deviating significantly from the active layer and maintain suitable laser oscillation characteristics.

### Advantageous Effects of Invention

According to one aspect of the present disclosure, it is possible to provide a semiconductor laser device capable of improving yield and suppressing loss of laser light.

### BRIEF DESCRIPTION OF DRAWINGS

FIG. 1 is a cross-sectional view showing a stacked structure of a semiconductor laser device according to a first embodiment.

FIG. 2 is a diagram showing an example of a manufacturing process of the semiconductor laser device of FIG. 1.

FIG. 3 is a diagram showing an example of a manufacturing process of the semiconductor laser device of FIG. 1.

FIG. 4 is a diagram showing an example of a manufacturing process of the semiconductor laser device of FIG. 1.

FIG. 5 is a diagram showing an example of a manufacturing process of the semiconductor laser device of FIG. 1.

FIG. 6 is a diagram showing an example of a manufacturing process of the semiconductor laser device of FIG. 1.

FIG. 7 is a diagram showing an example of a manufacturing process of the semiconductor laser device of FIG. 1.

FIG. 8 is a diagram showing an example of a manufacturing process of the semiconductor laser device of FIG. 1.

FIG. 9 is a cross-sectional view showing a stacked structure of a semiconductor laser device according to a second embodiment.

FIG. 10 is a cross-sectional view showing a stacked structure of a semiconductor laser device according to a third embodiment.

FIG. 11 is a diagram showing SIMS measurement results of the semiconductor laser device of FIG. 9.

FIG. 12 is a cross-sectional view showing a stacked structure of a semiconductor laser device according to a comparative example.

FIG. 13 is a cross-sectional view showing a stacked structure of a semiconductor laser device according to a third embodiment.

FIG. 14 is a diagram showing an example of a manufacturing process of the semiconductor laser device of FIG. 13.

FIG. 15 is a diagram showing an example of a manufacturing process of the semiconductor laser device of FIG. 13.

FIG. 16 is a diagram showing an example of mounting of the semiconductor laser device of FIG. 13.

FIG. 17 is a cross-sectional view showing a stacked structure of a semiconductor laser device according to a fourth embodiment.

FIG. 18 is a cross-sectional view showing a stacked structure of a semiconductor laser device according to a fifth embodiment.

FIG. 19 is a cross-sectional view showing an example of mounting of the semiconductor laser device of FIG. 18.

### DESCRIPTION OF EMBODIMENTS

Hereinafter, an embodiment of the present disclosure will be described in detail with reference to the drawings. In the following description, the same or corresponding elements are denoted by the same reference numerals, and overlapping descriptions will be omitted. The drawings may be simplified or exaggerated in part for ease of understanding, and the dimensional ratios are not limited to those shown in the drawings.

### First Embodiment

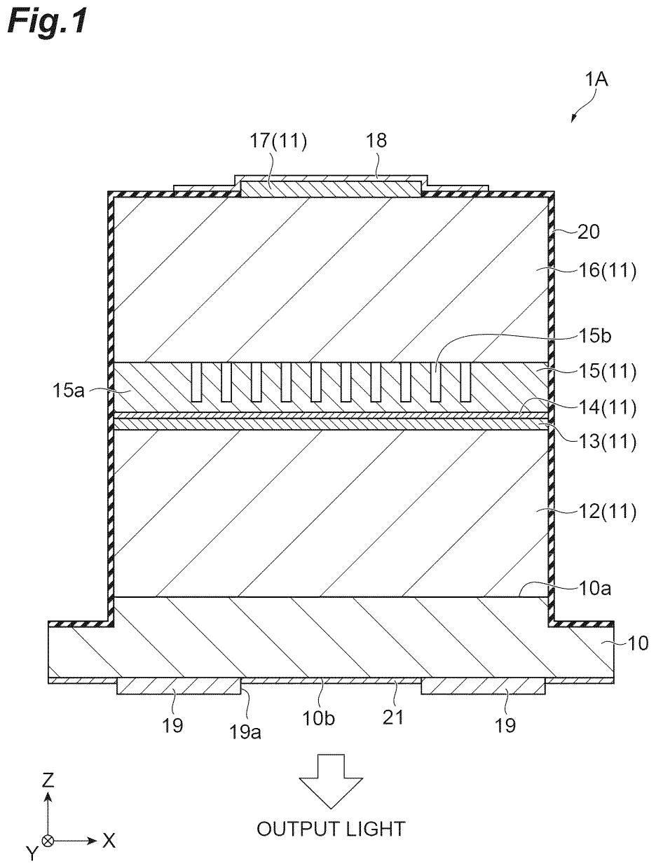

FIG. 1 is a cross-sectional view showing the stacked structure of a semiconductor laser device 1A according to a first embodiment. In this specification, for convenience, an XYZ orthogonal coordinate system is defined in which the stacking direction of the semiconductor laser device 1A is the Z-axis direction. In this embodiment, as an example, the semiconductor laser device 1A is configured as a photonic crystal surface emitting laser (PCSEL: Photonic Crystal Surface Emitting Laser). For example, the semiconductor laser device 1A is configured as an S-iPMSEL (Static-integrable Phase Modulating Surface Emitting Laser) that outputs a phase-controlled plane wave (laser light) in the Z-axis direction. The semiconductor laser device 1A outputs an optical image of an arbitrary two-dimensional shape including a direction perpendicular to the main surface 10a of the semiconductor substrate 10 (i.e., the Z-axis direction), a direction inclined with respect to the Z-axis direction, or both.

As shown in FIG. 1, the semiconductor laser device 1A includes a p-type semiconductor substrate 10 and a semiconductor multilayer structure 11 formed on the semiconductor substrate 10. The semiconductor laser device 1A has a so-called mesa-type shape. The semiconductor substrate 10 and the semiconductor multilayer structure 11 may be formed of InP-based semiconductors (compound semiconductors). The thickness direction of each layer of the semiconductor substrate 10 and the semiconductor multilayer structure 11 coincides with the Z-axis direction.

The semiconductor substrate 10 is, for example, an InP substrate doped with Zn (zinc). The semiconductor substrate 10 is formed in a substantially rectangular parallelepiped shape, and has a main surface 10a on which the semiconductor multilayer structure 11 is stacked, and a back surface 10b, which is a surface opposite to the main surface 10a and serves as the output surface for laser light. In this embodiment, as an example, the size of the semiconductor substrate 10 as viewed from the Z-axis direction is larger than that of the semiconductor multilayer structure 11. More specifically, when viewed from the Z-axis direction, the semiconductor substrate 10 is formed in a rectangular shape (in this embodiment, a substantially square shape) larger than the semiconductor multilayer structure 11, and the semiconductor multilayer structure 11 is provided at a substantially central portion of the main surface 10a of the semiconductor substrate 10. In addition, the thickness of the portion of the semiconductor substrate 10 overlapping the semiconductor multilayer structure 11 (i.e., the substantially central portion of the semiconductor substrate 10 as viewed from the Z-axis direction) is greater than the thickness of the portion of the semiconductor substrate 10 not overlapping the semiconductor multilayer structure 11 (i.e., the peripheral portion of the semiconductor substrate 10 formed in a rectangular ring shape as viewed from the Z-axis direction). In other words, the portion of the main surface 10a not overlapping the semiconductor multilayer structure 11 is recessed toward the back surface 10b compared to the portion overlapping the semiconductor multilayer structure 11. The thickness of the semiconductor substrate 10 (the portion overlapping the semiconductor multilayer structure 11) is, for example, 100 μm to 300 μm.

The semiconductor multilayer structure 11 is formed on the main surface 10a of the semiconductor substrate 10. The semiconductor multilayer structure 11 includes a p-type cladding layer 12, a non-doped guide layer 13, an active layer 14, an n-type guide layer 15, an n-type cladding layer 16, and an n-type contact layer 17. The p-type cladding layer 12, the non-doped guide layer 13, the active layer 14, the n-type guide layer 15, the n-type cladding layer 16, and the n-type contact layer 17 are stacked in this order on the main surface 10a of the semiconductor substrate 10. The energy bandgap of the p-type cladding layer 12 and the energy bandgap of the n-type cladding layer 16 are greater than the energy bandgap of the active layer 14.

When viewed from the Z-axis direction, each layer of the semiconductor multilayer structure 11 except for the n-type contact layer 17 is formed in a rectangular shape (in this embodiment, a substantially square shape) of the same size. On the other hand, the n-type contact layer 17 is formed in a rectangular shape (in this embodiment, a substantially square shape) smaller than the above layers when viewed from the Z-axis direction, and is disposed at a substantially central portion of the upper surface (the surface opposite to the n-type guide layer 15 side) of the n-type cladding layer 16.

Note that the semiconductor multilayer structure 11 may include layers other than those described above. For example, another layer (for example, a layer formed of InGaAs, InGaAsP, etc.) may be provided between the semiconductor substrate 10 and the p-type cladding layer 12.

The p-type cladding layer 12 is formed on the main surface 10a of the semiconductor substrate 10. That is, the p-type cladding layer 12 is disposed between the semiconductor substrate 10 and the active layer 14. The p-type cladding layer 12 may be formed, for example, of an InP layer doped with Zn as a p-type dopant. The impurity concentration of the p-type cladding layer 12 is, for example, 1×10¹⁷ to 1×10¹⁸ cm⁻³. The thickness of the p-type cladding layer 12 in the stacking direction (Z-axis direction) is, for example, 1000 nm or more.

The non-doped guide layer 13 is formed on the p-type cladding layer 12. That is, the non-doped guide layer 13 is disposed between the p-type cladding layer 12 and the active layer 14. Zn, which is a p-type dopant, is not doped in the non-doped guide layer 13. The non-doped guide layer 13 may be formed, for example, of InAlₓGa₁₋ₓAs (0<x≤1). Such a non-doped guide layer 13 of this composition can be suitably fabricated by using an InP substrate as the semiconductor substrate 10. The thickness of the non-doped guide layer 13 in the stacking direction (Z-axis direction) is 30 nm to 150 nm.

The active layer 14 is a light-emitting layer that generates light. The active layer 14 is disposed between the non-doped guide layer 13 and the n-type guide layer 15. The active layer 14 may have, for example, a multiple quantum well structure in which a barrier layer made of InAlGaAs or the like and a well layer made of InGaAs or the like are alternately stacked. The thickness of the active layer 14 in the stacking direction (Z-axis direction) is 5 nm to 200 nm.

The n-type guide layer 15 is disposed on the active layer 14. That is, the n-type guide layer 15 is disposed on a side of the active layer 14 opposite to a side where the non-doped guide layer 13 is located with respect to the active layer 14. The n-type guide layer 15 is provided with a fine structure portion having a fine concave-convex structure. In this embodiment, the n-type guide layer 15 includes a base layer 15a (i.e., the main body of the n-type guide layer 15) having a first refractive index, and a plurality of different refractive index regions 15b having a second refractive index different from the first refractive index. In this embodiment, as an example, the fine structure portion is constituted by the plurality of different refractive index regions 15b arranged two-dimensionally as viewed from the stacking direction (Z-axis direction).

Si as an n-type dopant is doped in the n-type guide layer 15 (base layer 15a). The n-type guide layer 15 (base layer 15a) may be formed, for example, of InAlGaAs, InGaAsP, or the like. The impurity concentration of the n-type guide layer 15 (base layer 15a) is, for example, 1×10¹⁷ to 1×10¹⁸ cm⁻³. The thickness of the n-type guide layer 15 in the stacking direction (Z-axis direction) is preferably 2 μm or less, and is, for example, 50 nm to 2000 nm. The different refractive index regions 15b may be constituted, for example, by voids. However, the configuration of the different refractive index regions 15b is not limited to the above. For example, the different refractive index regions 15b may be formed by embedding a semiconductor having a refractive index different from that of the base layer 15a in the voids. In addition, an inert gas such as argon or nitrogen, or a gas such as hydrogen or air, may be sealed inside the voids that constitute the different refractive index regions 15b.

The two-dimensional arrangement of the plurality of different refractive index regions 15b may include a substantially periodic structure. When the effective refractive index of the mode is n, the wavelength λ₀ (=(√2)×a×n, where a is the lattice constant) selected by the n-type guide layer 15 is included within the emission wavelength range of the active layer 14. The n-type guide layer 15 can selectively output light of a band-edge wavelength near λ₀ among the emission wavelengths of the active layer 14 to the outside. The laser light incident on the n-type guide layer 15 forms a predetermined mode corresponding to the arrangement of the different refractive index regions 15b in the n-type guide layer 15, and is emitted as a laser beam having a desired pattern from the back surface 10b of the semiconductor substrate 10 to the outside.

The n-type cladding layer 16 is disposed on the n-type guide layer 15. That is, the n-type cladding layer 16 is disposed on a side of the n-type guide layer 15 opposite to a side where the active layer 14 is located with respect to the n-type guide layer 15. The n-type cladding layer 16 may be formed, for example, of an InP layer doped with Si (silicon) as an n-type dopant. The impurity concentration of the n-type cladding layer 16 is, for example, 1×10¹⁷ to 1×10¹⁸ cm⁻³. The thickness of the n-type cladding layer 16 in the stacking direction (Z-axis direction) is, for example, 1000 nm or more.

The n-type contact layer 17 is disposed on the n-type cladding layer 16. That is, the n-type contact layer 17 is disposed on a side of the n-type cladding layer 16 opposite to a side where the n-type guide layer 15 is located with respect to the n-type cladding layer 16. Si as an n-type dopant is doped in the n-type contact layer 17. The n-type contact layer 17 may be formed, for example, of InGaAs, InGaAsP, InP, or the like. The impurity concentration of the n-type contact layer 17 is, for example, 5×10¹⁸ cm⁻³ or more. The thickness of the n-type contact layer 17 is, for example, 20 nm or more.

The semiconductor laser device 1A further includes an insulating film 20. The insulating film 20 is provided so as to cover the portion of the upper surface of the n-type cladding layer 16 where the n-type contact layer 17 is not provided, the side surfaces (surfaces intersecting the X-axis direction or Y-axis direction) of the semiconductor multilayer structure 11, and the portion of the main surface 10a of the semiconductor substrate 10 where the semiconductor multilayer structure 11 is not provided. That is, the insulating film 20 is provided so as to cover the surface of the portion provided on the main surface 10a of the semiconductor substrate 10 in the semiconductor laser device 1A, except for the upper surface of the n-type contact layer 17. As a result, the upper surface of the n-type contact layer 17 is exposed to the outside without being covered by the insulating film 20. The insulating film 20 may be formed, for example, of silicon nitride (e.g., SiN), silicon oxide (e.g., SiO₂), or the like.

The semiconductor laser device 1A further includes an electrode 18 (first electrode) provided on the n-type contact layer 17 and an electrode 19 (second electrode) provided on the back surface 10b of the semiconductor substrate 10. The electrode 18 is in ohmic contact with the n-type contact layer 17. The electrode 19 is in ohmic contact with the semiconductor substrate 10. In this embodiment, as an example, the electrode 18 is provided on the semiconductor multilayer structure 11 so as to cover the n-type contact layer 17 and a part of the insulating film 20 provided at the peripheral portion of the n-type contact layer 17. That is, the shape of the electrode 18 as viewed from the Z-axis direction is a rectangular shape (in this embodiment, a substantially square shape) slightly larger than the n-type contact layer 17. The electrode 19 is formed in a rectangular ring shape having an opening 19a of a rectangular shape (in this embodiment, a substantially square shape) that exposes the central portion of the back surface 10b. On the portion of the back surface 10b of the semiconductor substrate 10 where the electrode 19 is not provided (including the region inside the opening 19a), an antireflection film 21 is provided. The antireflection film 21 may be formed, for example, of a single-layer dielectric film or a multilayer dielectric film of silicon nitride (e.g., SiN), silicon oxide (e.g., SiO2), or the like. Note that, since the antireflection film 21 is for preventing reflection of the laser light output from inside the opening 19a, the portion of the antireflection film 21 provided in a region other than the opening 19a (i.e., the portion located outside the electrode 19 as viewed from the Z-axis direction) may be removed.

When a drive current is supplied between the electrode 18 and the electrode 19, recombination of electrons and holes occurs in the active layer 14, and the active layer 14 emits light. The electrons and holes contributing to this emission, as well as the generated light, are efficiently confined between the p-type cladding layer 12 and the n-type cladding layer 16. The light emitted from the active layer 14 enters the interior of the n-type guide layer 15 and forms a predetermined mode corresponding to the lattice structure (i.e., the fine structure formed by the plurality of different refractive index regions 15b) in the n-type guide layer 15. The laser light emitted from the n-type guide layer 15 is output to the outside of the semiconductor laser device 1A either directly through the opening 19a from the back surface 10b, or after being reflected by the electrode 18, through the opening 19a from the back surface 10b.

Note that, by changing the electrode shape, it is also possible to emit laser light from the surface (upper surface) of the n-type contact layer 17. For example, by providing an opening in the electrode 18 on the upper surface of the n-type contact layer 17 without providing the opening 19a in the electrode 19, the laser light can be emitted to the outside from the upper surface of the n-type contact layer 17 through the opening of the electrode 18. In this case, the antireflection film 21 may be provided inside and around the opening of the electrode 18, instead of on the back surface 10b of the semiconductor substrate 10.

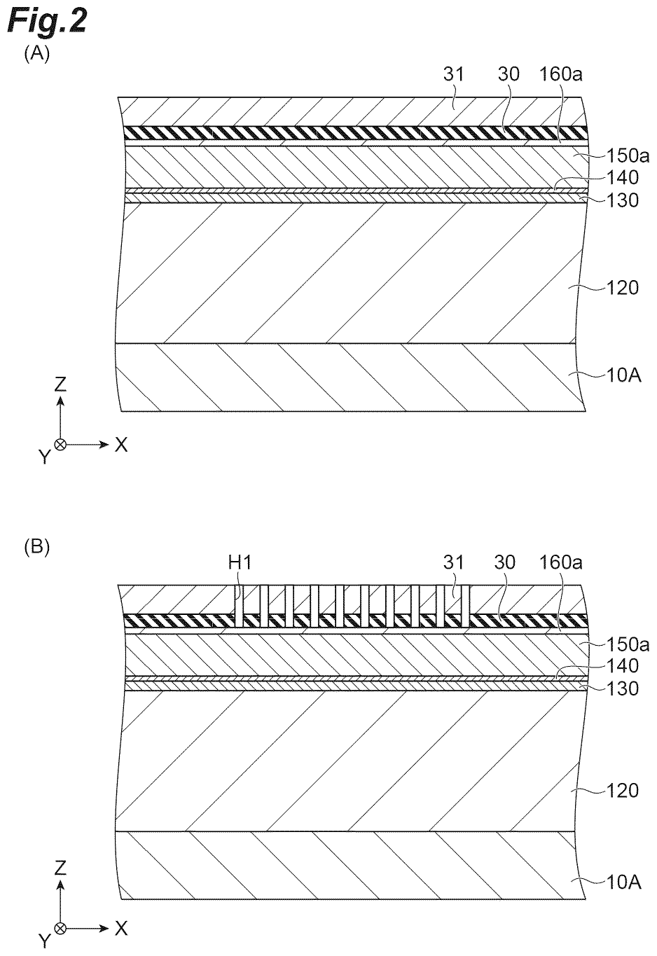

Next, with reference to FIGS. 2 to 8, an example of a manufacturing method of the semiconductor laser device 1A will be described.

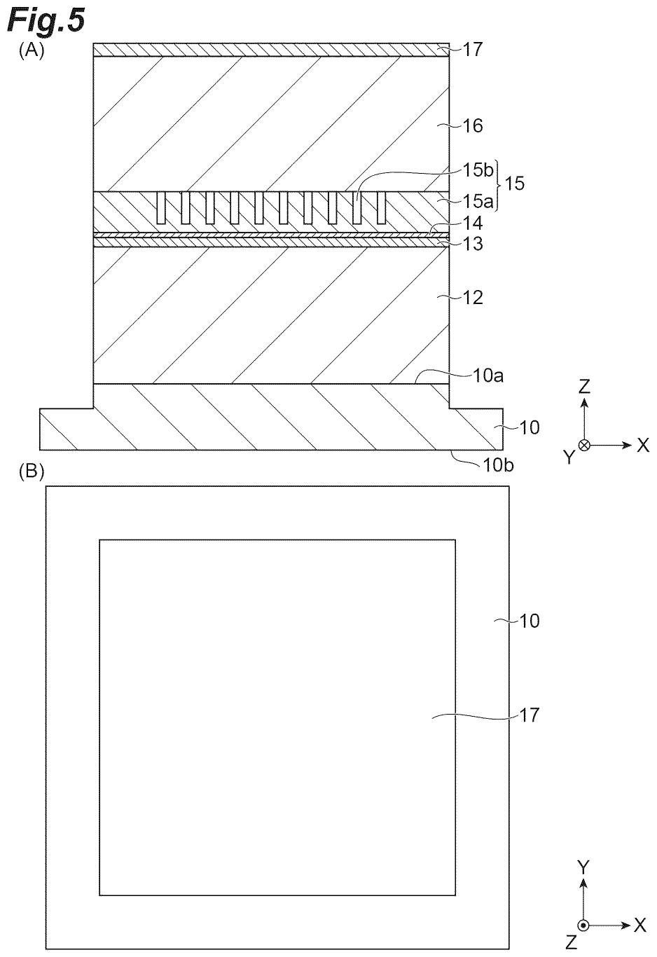

First, as shown in (A) of FIG. 2, by using a metal-organic chemical vapor deposition (MOCVD) method, a molecular beam epitaxy (MBE) method, or the like, a p-type cladding layer 120, a non-doped guide layer 130, an active layer 140, a base layer 150a, and an n-type cap layer 160a are epitaxially grown on a semiconductor substrate 10A (first growth process). Here, each of the semiconductor substrate 10A, the p-type cladding layer 120, the non-doped guide layer 130, the active layer 140, and the base layer 150a is a portion that will become the semiconductor substrate 10, the p-type cladding layer 12, the non-doped guide layer 13, the active layer 14, and the base layer 15a, respectively, of each of a plurality of semiconductor laser devices 1A after a device separation process (see FIG. 5) described later. That is, the structure shown in (A) of FIG. 2 is in a wafer state including portions that will become a plurality of semiconductor laser devices 1A. The n-type cap layer 160a is a portion that constitutes a part (the portion located near the n-type guide layer 150) of the n-type cladding layer 16 of each of the plurality of semiconductor laser devices 1A. The n-type cap layer 160a is provided for protecting (preventing oxidation of) the lower layers (i.e., the active layer 140, the base layer 150a, etc.) that may contain Al. In addition, for example, an insulating film 30 made of SiN, SiO₂, or the like is formed on the n-type cap layer 160a by a PCVD method, and a resist 31 (EB resist) is applied on the insulating film 30.

Subsequently, as shown in (B) of FIG. 2, a two-dimensional fine pattern is drawn on the resist 31 using an electron beam drawing apparatus and developed, thereby forming a two-dimensional fine pattern (a part of holes H1) in the resist 31. Thereafter, by etching (for example, reactive ion etching) the insulating film 30 using the resist 31 as a mask, the two-dimensional fine pattern is also formed in the insulating film 30. In this way, a two-dimensional fine pattern (a plurality of holes H1) is formed in the resist 31 and the insulating film 30.

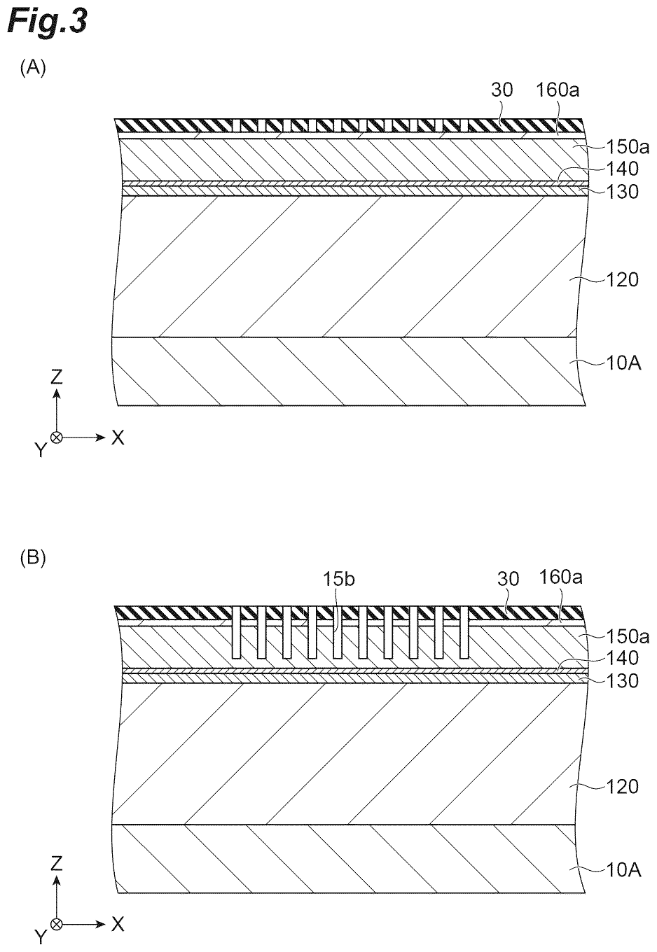

Next, as shown in (A) of FIG. 3, the resist 31 is removed (stripped). Subsequently, as shown in (B) of FIG. 3, by etching (for example, dry etching) the n-type cap layer 160a and the base layer 150a using the insulating film 30 as a mask, the above-described different refractive index regions 15b are formed in the base layer 150a.

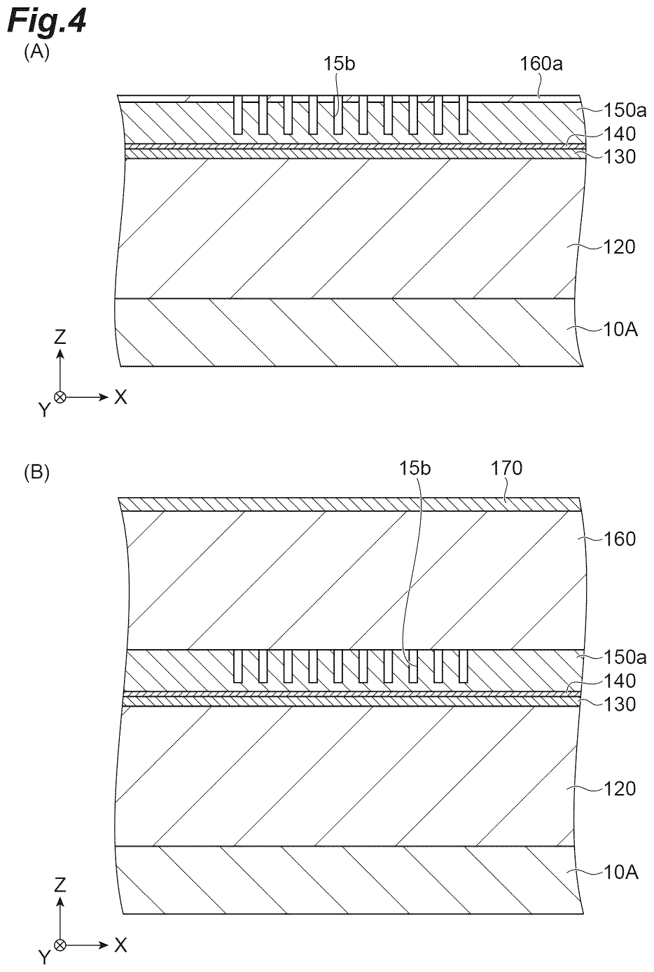

Next, as shown in (A) of FIG. 4, the insulating film 30 is removed. Subsequently, as shown in (B) of FIG. 4, an n-type cladding layer 160 and an n-type contact layer 170 are epitaxially grown (second growth process). The n-type cladding layer 160 and the n-type contact layer 170 are portions that will become the n-type cladding layer 16 and the n-type contact layer 17, respectively, of each of a plurality of semiconductor laser devices 1A after a device separation process (see FIG. 5) described later. Note that the n-type cap layer 160a formed in the first growth process is integrated with the n-type cladding layer 160 by the second growth process.

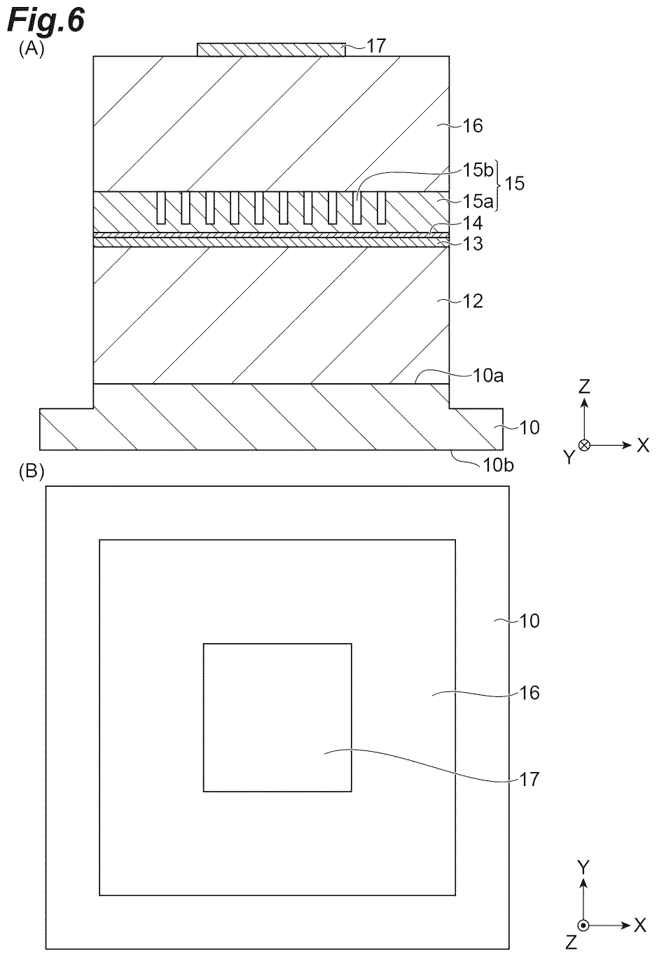

Next, as shown in FIG. 5, device separation (dicing) and mesa formation processing of the structure (wafer) shown in (B) of FIG. 4 are performed. As a result, a plurality of structures are obtained in a state before the electrodes 18, 19 and the insulating film 20 described above are provided, in which the n-type contact layer 17 is provided so as to cover the entire upper surface of the n-type cladding layer 16. (B) of FIG. 5 shows a plan view (as viewed from the positive Z-axis direction) of the structure shown in (A) of FIG. 5. The processes shown in FIGS. 6 to 8 described later are performed on each of the plurality of structures thus obtained, thereby obtaining a plurality of semiconductor laser devices 1A.

Next, as shown in FIG. 6, the portion of the n-type contact layer 17 provided at the peripheral portion of the upper surface of the n-type cladding layer 16 is removed. (B) of FIG. 6 shows a plan view (as viewed from the positive Z-axis direction) of the structure shown in (A) of FIG. 6.

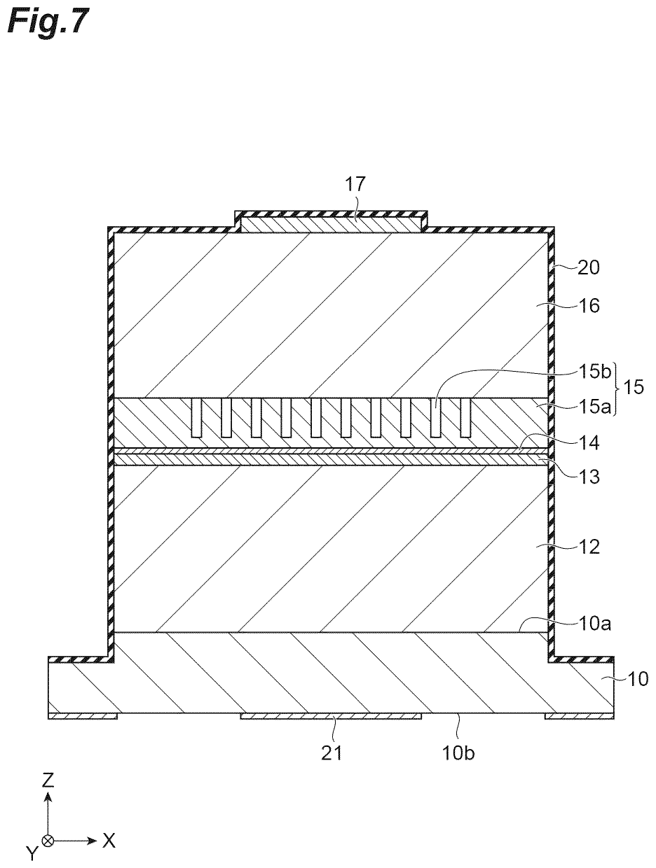

Next, as shown in FIG. 7, the insulating film 20 is formed so as to cover the upper surface and side surfaces of the n-type contact layer 17, the portion of the upper surface of the n-type cladding layer 16 where the n-type contact layer 17 is not provided, the side surfaces (surfaces intersecting the X-axis direction or Y-axis direction) of the semiconductor multilayer structure 11, and the portion of the main surface 10a of the semiconductor substrate 10 where the semiconductor multilayer structure 11 is not provided. In addition, an antireflection film 21 is provided on the back surface 10b of the semiconductor substrate 10. For example, after the antireflection film 21 is formed on the entire back surface 10b, the portion corresponding to the region (rectangular ring-shaped region as viewed from the Z-axis direction) where the electrode 19 is to be disposed is removed, thereby obtaining the state shown in FIG. 7.

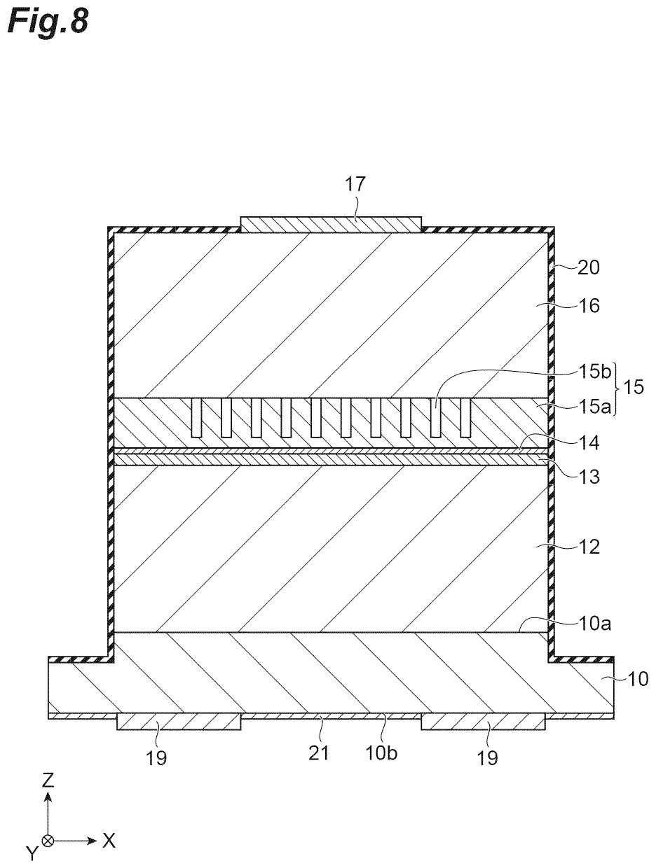

Next, as shown in FIG. 8, the electrode 19 is formed on the back surface 10b. In addition, by removing the portion of the insulating film 20 covering the n-type contact layer 17, a contact opening for bringing the n-type contact layer 17 and the electrode 18 into contact is formed. Subsequently, the electrode 18 is formed on the n-type contact layer 17, and the entire structure is heated to make the electrode 19 adhere to the semiconductor substrate 10 and the electrode 18 adhere to the n-type contact layer 17. In this way, the semiconductor laser device 1A having the structure shown in FIG. 1 is obtained.

### Effects of the First Embodiment

In the semiconductor laser device 1A described above, the non-doped guide layer 13 formed of InAlₓGa₁₋ₓAs can suitably suppress the diffusion of the p-type dopant (Zn) from the p-type cladding layer 12 toward the n-type cladding layer 16. As a result, it becomes easy to reproducibly set the position of the p-n junction interface at a desired position inside or near the active layer 14. Furthermore, by making the n-type guide layer 15 thicker than the non-doped guide layer 13, the waveguide mode of the laser light generated in the active layer 14 can be shifted toward the n-type layers (the n-type guide layer 15 and the n-type cladding layer 16), which have a smaller absorption loss for the laser light than the p-type layers (the p-type cladding layer 12 and the p-type semiconductor substrate 10). This makes it possible to suitably suppress the absorption loss of the laser light in the p-type layers. Therefore, according to the semiconductor laser device 1A, it is possible to improve yield and suppress loss of laser light. In addition, as shown in FIG. 1, in the semiconductor laser device 1A, by using a p-type semiconductor substrate 10, it is possible to adopt a configuration in which the electrodes 18 and 19 for driving the semiconductor laser device 1A are disposed on both sides sandwiching the semiconductor multilayer structure 11 and the semiconductor substrate 10.

In addition, Si is doped in the n-type guide layer 15 and the n-type cladding layer 16. By using Si, which is less likely to thermally diffuse, as the n-type dopant, it is possible to suitably suppress the movement of the p-n junction interface due to diffusion of the n-type dopant toward the p-type layer side. As a result, the position of the p-n junction interface can be adjusted to a desired position with even better reproducibility, thereby further improving yield.

Furthermore, the thickness of the n-type guide layer 15 in the stacking direction (Z-axis direction) is 2 μm or less (in this embodiment, as an example, 50 nm to 2000 nm). As described above, by making the thickness of the n-type guide layer 15 greater than that of the non-doped guide layer 13, the waveguide mode can be shifted toward the n-type layer side. However, if the n-type guide layer 15 is made too thick, the waveguide mode may deviate significantly from the active layer 14, making it difficult to obtain suitable laser oscillation characteristics (the relationship between the injection current and the optical output). In contrast, by limiting the thickness of the n-type guide layer 15 to a certain value or less (2 μm or less) as described above, the occurrence of the above problem can be suppressed. In addition, if the n-type guide layer 15, which has a high refractive index, is made too thick, not only the fundamental mode light but also higher-order mode light may be generated, and the waveguide mode may become unstable, resulting in a disturbed beam pattern. By limiting the thickness of the n-type guide layer 15 to a certain value or less as described above, the occurrence of such problems can also be suppressed.

Furthermore, the thickness of the non-doped guide layer 13 in the stacking direction (Z-axis direction) is 30 nm to 150 nm. By setting the thickness of the non-doped guide layer 13 to 30 nm or more, the diffusion of Zn from the p-type cladding layer 12 described above can be suitably prevented. Furthermore, by setting the thickness of the non-doped guide layer 13 to 150 nm or less, it is possible to prevent the p-type cladding layer 12 from being too far from the active layer 14. As a result, it is possible to suppress the p-n junction interface from deviating significantly from the active layer 14, and thus prevent deterioration of the laser oscillation characteristics. In addition, by limiting the thickness of the non-doped guide layer 13 to a certain value or less (150 nm or less), it is also possible to reduce the amount of Al (contained in the non-doped guide layer 13), which is prone to degradation, and suppress a decrease in device lifetime.

Furthermore, the n-type guide layer 15 is provided with a fine structure portion (in this embodiment, a portion constituted by the plurality of different refractive index regions 15b) having a fine concave-convex structure. By providing the fine structure portion in the n-type guide layer 15, which is located on the side opposite to the semiconductor substrate 10 with respect to the active layer 14 and is thicker than the other guide layer (the non-doped guide layer 13), it is possible to process the fine structure portion with high accuracy and improve the stability of the fine structure portion. In addition, by providing the plurality of different refractive index regions 15b as the fine structure portion in the n-type guide layer 15 as in this embodiment, the semiconductor laser device 1A can function as a photonic crystal surface emitting laser (in this embodiment, as an example, an S-iPMSEL, which is a type of photonic crystal surface emitting laser (PCSEL)).

Furthermore, the thickness of the n-type guide layer 15 in the stacking direction (Z-axis direction) is preferably set to 1.5 times or more (more preferably 2 times or more) the thickness of the non-doped guide layer 13 in the stacking direction. As an example, when the thickness of the non-doped guide layer 13 is 50 nm, the thickness of the n-type guide layer 15 is preferably set to 75 nm or more (more preferably 100 nm or more). When the fine structure portion (in this embodiment, a portion constituted by the plurality of different refractive index regions 15b) is provided in the n-type guide layer 15, the waveguide mode shifts toward the p-type layer side compared to the case where the fine structure portion is not provided (i.e., when the n-type guide layer 15 is constituted only by the base layer 15a). By making the thickness of the n-type guide layer 15 1.5 times or more that of the non-doped guide layer 13, the degree of such shift can be reduced, and it is possible to suppress the waveguide mode from deviating significantly from the active layer 14 and maintain suitable laser oscillation characteristics. In addition, by making the thickness of the n-type guide layer 15 2 times or more that of the non-doped guide layer 13, the above effect can be obtained more reliably.

### Second Embodiment

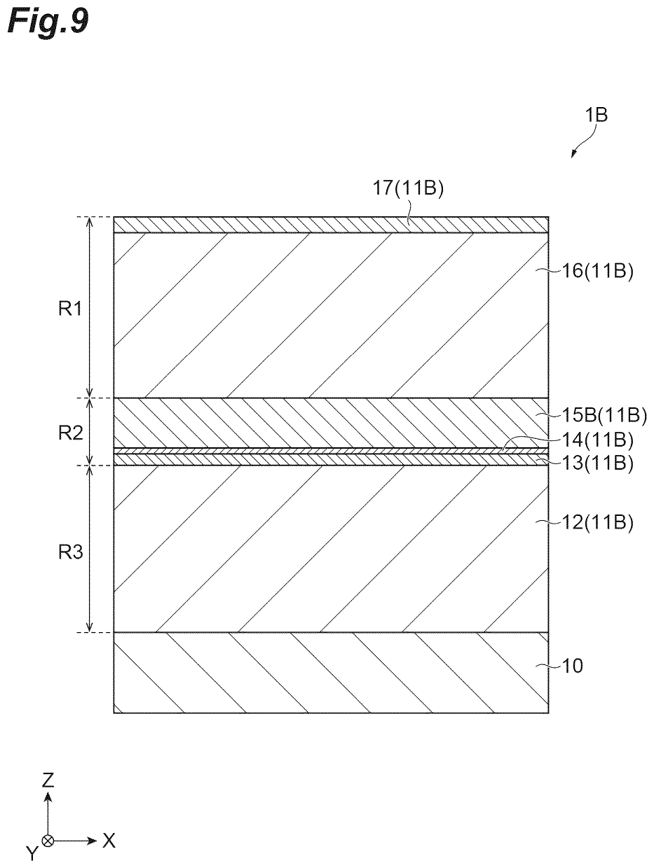

A semiconductor laser device 1B according to a second embodiment will be described with reference to FIG. 9. In FIG. 9, the illustration of electrodes (corresponding to the electrodes 18 and 19 of the semiconductor laser device 1A) is omitted. The semiconductor multilayer structure 11B of the semiconductor laser device 1B mainly differs from the semiconductor multilayer structure 11 of the semiconductor laser device 1A in that it includes an n-type guide layer 15B consisting only of a base layer 15a, instead of the n-type guide layer 15. That is, the semiconductor laser device 1B mainly differs from the semiconductor laser device 1A in that it is not configured as a photonic crystal surface emitting laser (PCSEL). More specifically, the semiconductor laser device 1B is configured as an edge-emitting laser diode in which laser light resonates between end faces of the active layer 14 facing each other in a resonance direction (for example, the X-axis direction) perpendicular to the stacking direction (Z-axis direction), and the laser light is emitted to the outside from the end faces.

Even in the edge-emitting semiconductor laser device 1B, the same effects as those of the above-described surface-emitting semiconductor laser device 1A can be achieved. That is, the non-doped guide layer 13 formed of InAlₓGa₁₋ₓAs can suitably suppress the diffusion of the p-type dopant (Zn) from the p-type cladding layer 12 toward the n-type cladding layer 16 side. As a result, it becomes easy to reproducibly set the position of the p-n junction interface at a desired position inside or near the active layer 14. Furthermore, by making the n-type guide layer 15B thicker than the non-doped guide layer 13, the waveguide mode of the laser light generated in the active layer 14 can be shifted toward the n-type layers (the n-type guide layer 15B and the n-type cladding layer 16), which have a smaller absorption loss for the laser light than the p-type layers (the p-type cladding layer 12 and the p-type semiconductor substrate 10). This makes it possible to suitably suppress the absorption loss of the laser light in the p-type layers.

In addition, in the edge-emitting semiconductor laser device 1B, by making the n-type guide layer 15B thicker than the non-doped guide layer 13 and shifting the waveguide mode toward the n-type layer side as described above, the following effects can be further obtained. If, in the resonance of the laser light, the light is too concentrated in the active layer 14 (especially at the end faces of the active layer 14), the bandgap of the active layer 14 shrinks due to the generated heat, making it easier for the light to be further concentrated in the active layer 14, and the active layer 14 is more likely to deteriorate. As a result, the product lifetime of the semiconductor laser device may be shortened. In contrast, by shifting the waveguide mode toward the n-type layer side as described above, it is possible to suppress the laser light resonating in the resonance direction (for example, the X-axis direction) from being concentrated at the end faces of the active layer 14, thereby suppressing the deterioration of the active layer 14 and, consequently, prolonging the product lifetime of the semiconductor laser device 1B. Note that the above effect is particularly significant in the edge-emitting semiconductor laser device 1B, but since a component of laser light resonating in the resonance direction (for example, the X-axis direction) may also be generated in the surface-emitting semiconductor laser device 1A, the same effect can be achieved in the semiconductor laser device 1A as well.

### Third Embodiment

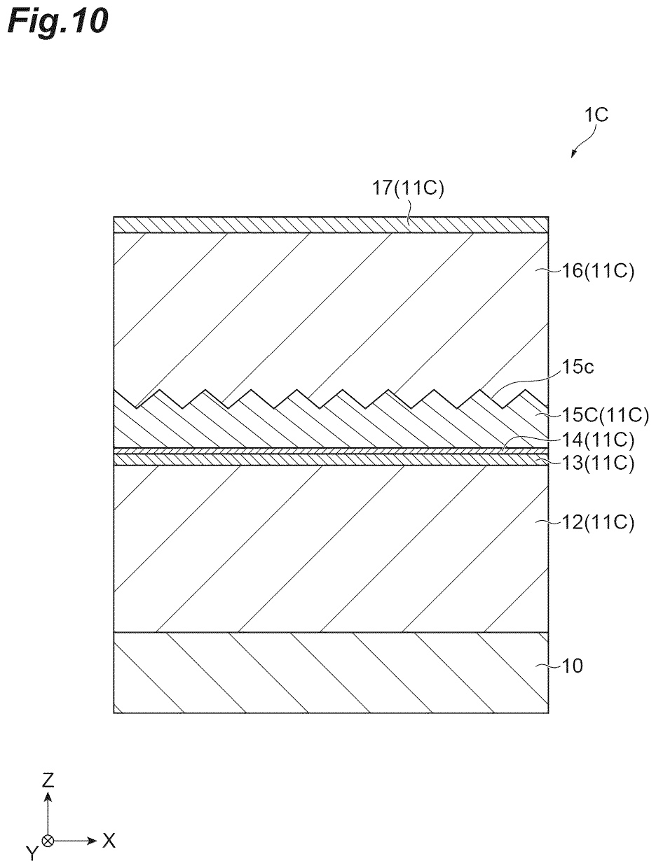

A semiconductor laser device 1C according to a third embodiment will be described with reference to FIG. 10. In FIG. 10, the illustration of electrodes (corresponding to the electrodes 18 and 19 of the semiconductor laser device 1A) is omitted. The semiconductor multilayer structure 11C of the semiconductor laser device 1C mainly differs from the semiconductor multilayer structure 11 of the semiconductor laser device 1A in that it includes an n-type guide layer 15C instead of the n-type guide layer 15. The semiconductor laser device 1C is configured as an edge-emitting laser diode similar to the semiconductor laser device 1B. The n-type guide layer 15C differs from the n-type guide layer 15B of the semiconductor laser device 1B in that it has a diffraction grating 15c (fine structure portion) distributed along the resonance direction (for example, the X-axis direction) of the active layer 14 perpendicular to the stacking direction.

Even in the semiconductor laser device 1C, the same effects as those of the above-described semiconductor laser devices 1A and 1B can be achieved. In addition, by providing the diffraction grating 15c in the n-type guide layer 15C, the semiconductor laser device 1C can function as a distributed feedback (DFB) semiconductor laser.

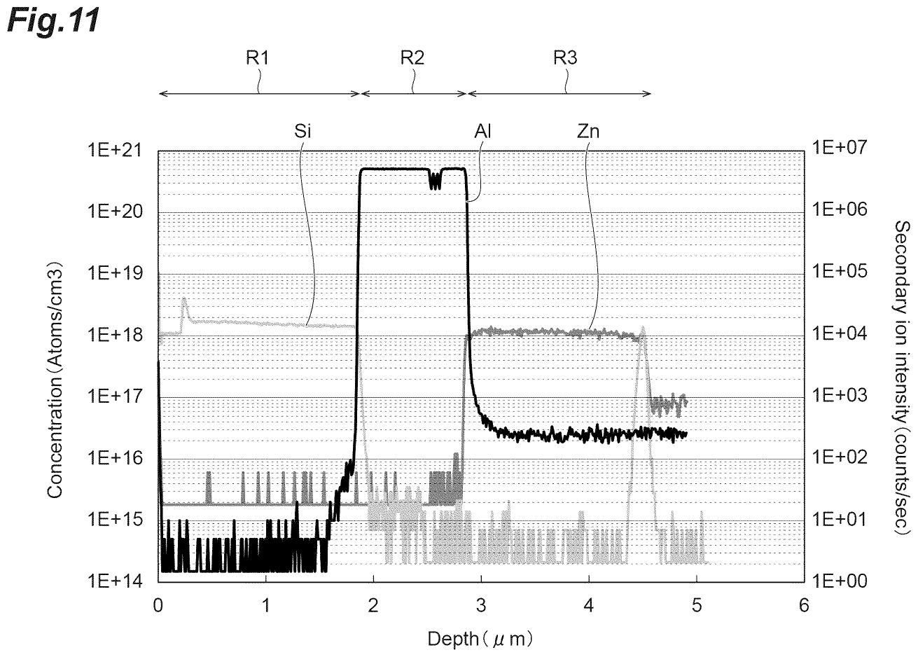

Next, with reference to FIG. 11, the effect (Zn diffusion prevention effect) of the embodiment of the present disclosure (as an example, the structure of the semiconductor laser device 1B shown in FIG. 9) will be supplemented. FIG. 11 is a graph showing the results of SIMS analysis of the elements contained in each layer of the semiconductor multilayer structure 11B of the semiconductor laser device 1B. In FIG. 11, the horizontal axis indicates the distance (depth) in the direction toward the semiconductor substrate 10, with the upper surface of the n-type contact layer 17 as the origin (0) and the positive direction being toward the semiconductor substrate 10 (the negative Z-axis direction). The left vertical axis indicates the concentration of Zn and Si (atoms/cm³: number of atoms per cubic centimeter), and the right vertical axis indicates the secondary ion intensity of Al (counts/sec: number of secondary ions detected per second). The regions R1, R2, and R3 shown in the graph of FIG. 11 correspond to the regions R1, R2, and R3 shown in FIG. 9. That is, region R1 is a region including the n-type contact layer 17 and the n-type cladding layer 16, region R2 is a region including the n-type guide layer 15B, the active layer 14, and the non-doped guide layer 13, and region R3 is a region including the p-type cladding layer 12.

As shown in the graph of FIG. 11, in the structure of this embodiment (the semiconductor laser device 1B), it was confirmed that the non-doped guide layer 13 suitably suppresses the diffusion of Zn (i.e., the diffusion of Zn from region R3 to region R2). In addition, it was confirmed that by using an n-type dopant (Si) that is less likely to diffuse, diffusion of the n-type dopant from region R1 to region R2 is also prevented. Although the above SIMS analysis was performed on the structure of the semiconductor laser device 1B, since the semiconductor laser devices 1A and 1C also include the same non-doped guide layer 13 as the semiconductor laser device 1B, it is considered that similar results can be obtained.

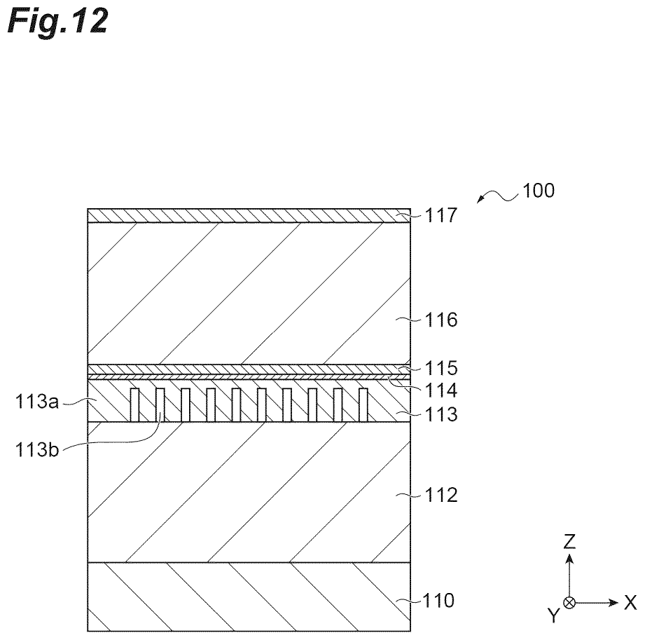

Next, a semiconductor laser device 100 according to a comparative example shown in FIG. 12 will be described, and the effects of the embodiment of the present disclosure (for example, the semiconductor laser devices 1A and 1C) in the case where a fine structure portion is provided will be supplemented. The semiconductor laser device 100 shown in FIG. 12 includes an n-type semiconductor substrate 110, and an n-type cladding layer 112, an n-type guide layer 113, an active layer 114, a non-doped guide layer 115, a p-type cladding layer 116, and a p-type contact layer 117, which are stacked in this order on the semiconductor substrate 110. Thus, the semiconductor laser device 100 has a structure in which the n-type and p-type structures of the semiconductor laser device 1A are reversed. That is, in the semiconductor laser device 1A, by using a p-type semiconductor substrate 10, a p-type layer is disposed below the active layer 14 (the side where the semiconductor substrate 10 is located with respect to the active layer 14), and an n-type layer is disposed above the active layer 14. In contrast, in the semiconductor laser device 100, by using an n-type semiconductor substrate 110, an n-type layer is disposed below the active layer 114 (the side where the semiconductor substrate 110 is located with respect to the active layer 114), and a p-type layer is disposed above the active layer 114.

The semiconductor substrate 110 is an InP substrate doped with S (sulfur). The n-type cladding layer 112 has the same configuration as the n-type cladding layer 16 of the semiconductor laser device 1A. The n-type guide layer 113 has the same configuration as the n-type guide layer 15 of the semiconductor laser device 1A. That is, the n-type guide layer 113 includes a base layer 113a similar to the base layer 15a and a plurality of different refractive index regions 113b similar to the plurality of different refractive index regions 15b. The active layer 114 has the same configuration as the active layer 14 of the semiconductor laser device 1A. The non-doped guide layer 115 has the same configuration as the non-doped guide layer 13 of the semiconductor laser device 1A. The p-type cladding layer 116 has the same configuration as the p-type cladding layer 12 of the semiconductor laser device 1A. The p-type contact layer 117 is formed of an InGaAs layer doped with Zn as a p-type dopant.

Even in the semiconductor laser device 100 configured as described above, the non-doped guide layer 115 can suppress the diffusion of the p-type dopant (Zn) from the p-type cladding layer 116 toward the n-type cladding layer 112. However, in the structure of the semiconductor laser device 100, the n-type guide layer 113, which can secure a layer thickness for providing a fine structure portion, is provided below the active layer 114 (i.e., between the active layer 114 and the semiconductor substrate 110). Therefore, the crystal surface of the layer (n-type guide layer 113) immediately below the active layer 114 (on the semiconductor substrate 110 side) is roughened by the formation of the fine structure portion (the plurality of different refractive index regions 113b). Therefore, in the case of manufacturing the semiconductor laser device 100 by growing each layer on the semiconductor substrate 110 as described in the manufacturing process of the above-described semiconductor laser device 1A, the manufacturing difficulty for accurately forming the active layer 114 on the roughened n-type guide layer 113 increases. This is also the case when a diffraction grating 15c (see FIG. 10) as a fine structure portion is formed in the n-type guide layer 113. In contrast, in the above-described semiconductor laser devices 1A and 1C, by using a p-type semiconductor substrate 10, it is possible to provide a guide layer (n-type guide layer 15) that can secure a layer thickness for forming a fine structure portion above the active layer 14 (i.e., on the side opposite to the side where the semiconductor substrate 10 is located with respect to the active layer 14). Therefore, as shown in (A) of FIG. 2, after easily and accurately forming the active layer 14, it is possible to perform processing to form a fine structure portion in the n-type guide layer 15 above the active layer 14. Therefore, according to the semiconductor laser devices 1A and 1C, in the case where a fine structure portion is provided in the guide layer, the manufacturing process can be simplified and the yield can be improved compared to the semiconductor laser device 100.

### Fourth Embodiment

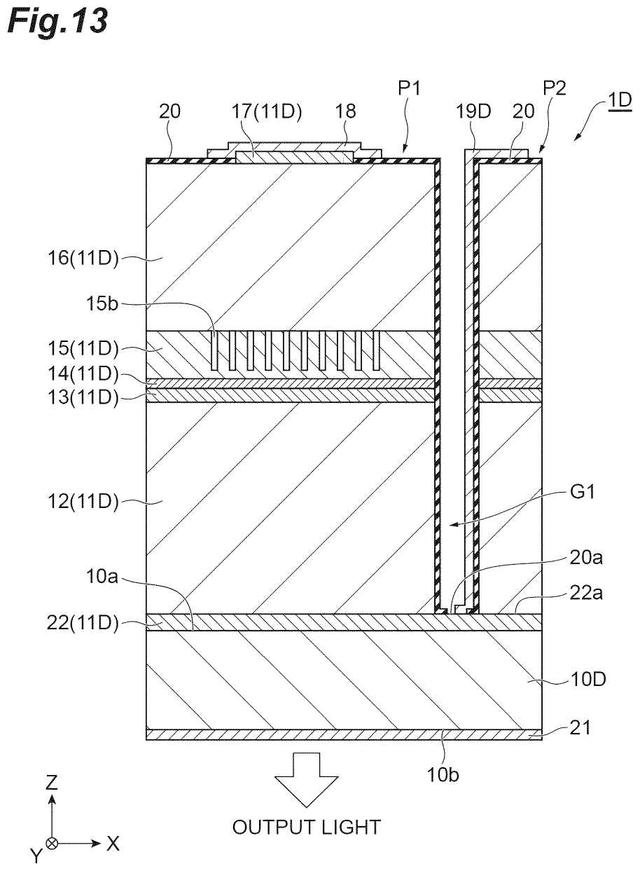

A semiconductor laser device 1D according to a fourth embodiment will be described with reference to FIGS. 13 to 15. As shown in FIG. 13, the semiconductor laser device 1D mainly differs from the semiconductor laser device 1A in that it includes a semiconductor substrate 10D, a semiconductor multilayer structure 11D, and an electrode 19D instead of the semiconductor substrate 10, the semiconductor multilayer structure 11, and the electrode 19. The semiconductor laser device 1D is configured as a surface-emitting laser diode similar to the semiconductor laser device 1A.

The semiconductor substrate 10D differs from the p-type semiconductor substrate 10 in that it is an n-type semiconductor substrate. Other configurations such as the shape of the semiconductor substrate 10D are the same as those of the semiconductor substrate 10. The semiconductor substrate 10D may be formed, for example, of an InP substrate doped with S (sulfur), an InP substrate doped with Sn (tin), or the like.

The semiconductor multilayer structure 11D differs from the semiconductor multilayer structure 11 in that it further includes a p-type contact layer 22. The p-type contact layer 22 is provided in contact with the p-type cladding layer 12. In this embodiment, the p-type contact layer 22 is disposed between the main surface 10a of the semiconductor substrate 10D and the p-type cladding layer 12. Note that the p-type contact layer 22 is not limited to being formed as a single layer and may be formed of a plurality of layers. For example, the p-type contact layer 22 may include, as a part thereof, a layer (also called a buffer layer) provided in contact with the p-type cladding layer 12 to reduce the electrical resistance with the p-type cladding layer 12.

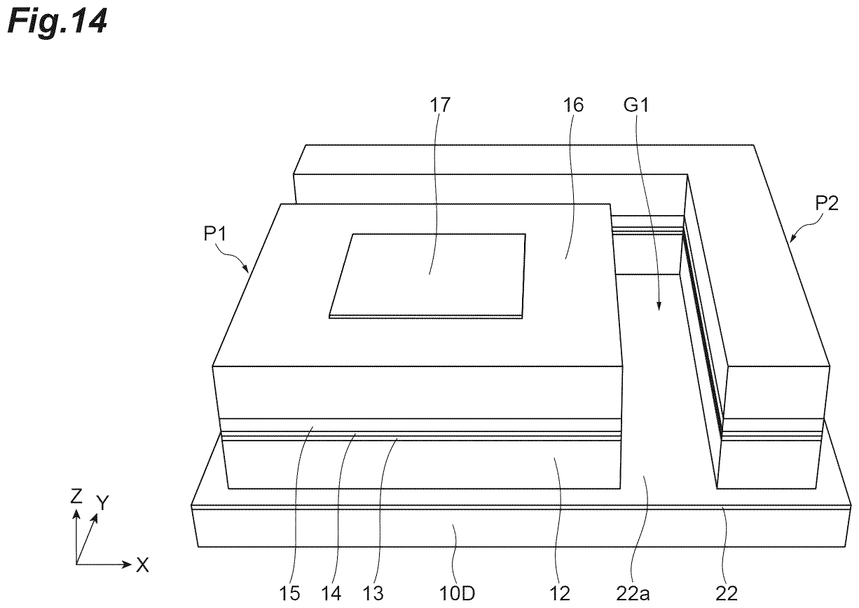

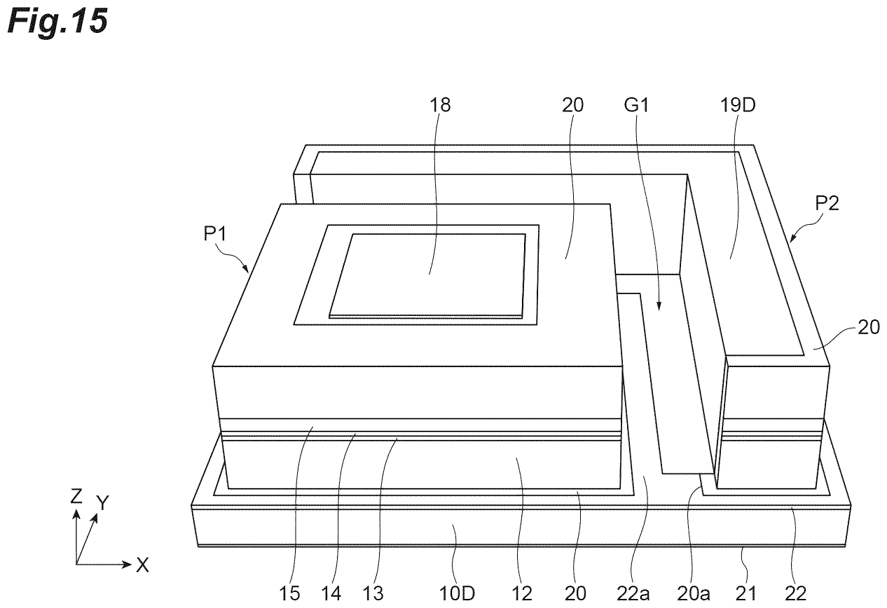

The semiconductor multilayer structure 11D is provided with a groove G1 extending from a surface (in this embodiment, the upper surface of the n-type cladding layer 16) of the semiconductor multilayer structure 11D opposite to the semiconductor substrate 10D side to a surface 22a (first surface) of the p-type contact layer 22 opposite to the semiconductor substrate 10D side. As shown in FIGS. 14 and 15, in this embodiment, as an example, the groove G1 is provided in an L-shape as viewed from the Z-axis direction. The semiconductor multilayer structure 11D is separated by the groove G1 into a light-emitting portion P1 (first portion) and a non-light-emitting portion P2 (second portion). The light-emitting portion P1 is a portion configured to output (surface-emitting) laser light and is formed in a substantially square shape as viewed from the Z-axis direction. The non-light-emitting portion P2 is a portion that does not output laser light and is formed in an L-shape along the outer periphery of the groove G1. The width (X-axis direction or Y-axis direction) of the light-emitting portion P1 is, for example, about 500 μm.

In the semiconductor laser device 1D, the insulating film 20 is provided on the upper surface of the light-emitting portion P1 (n-type cladding layer 16), the inner surface of the groove G1 (the side surface of the light-emitting portion P1, the side surface of the non-light-emitting portion P2, and the upper surface of the p-type contact layer 22), and the upper surface of the non-light-emitting portion P2 (n-type cladding layer 16). In the portion of the insulating film 20 corresponding to the bottom of the groove G1 (i.e., the upper portion of the p-type contact layer 22), an opening 20a is formed to expose the surface 22a of the p-type contact layer 22. As an example, the opening 20a is provided throughout the L-shaped groove G1. That is, as viewed from the Z-axis direction, the opening 20a is formed in an L-shape along the groove G1.

In the semiconductor multilayer structure 11D, the electrode 19D facing the electrode 18 is provided so as to extend from the surface of the non-light-emitting portion P2 opposite to the semiconductor substrate 10D side, along the side surface of the non-light-emitting portion P2, to the surface 22a of the p-type contact layer 22. That is, in this embodiment, the electrode 19D is provided on the insulating film 20 formed on the upper surface and side surface of the non-light-emitting portion P2, and extends to the opening 20a of the insulating film 20, so as to contact the surface 22a of the p-type contact layer 22 exposed by the opening 20a.

Next, with reference to FIGS. 14 and 15, an example of a manufacturing method of the semiconductor laser device 1D will be described. Note that FIGS. 14 and 15 are schematic diagrams, and in reality, some parts of members with thickness are not shown with thickness. First, as shown in FIG. 14, the semiconductor multilayer structure 11D is grown on the semiconductor substrate 10D, and the groove G1 is formed by etching or the like. Next, as shown in FIG. 15, the insulating film 20 is formed, the electrodes 18 and 19D are formed in order, and the antireflection film 21 is formed. In this way, the semiconductor laser device 1D having the structure shown in FIG. 13 is obtained.

In the semiconductor laser device 1D, by using the n-type semiconductor substrate 10D, in the case where the semiconductor laser device 1D is configured as a surface-emitting laser that emits laser light from the surface (back surface 10b) of the semiconductor substrate 10D opposite to the semiconductor multilayer structure 11D side, the absorption loss of the laser light in the semiconductor substrate 10D can be reduced compared to the case where a p-type semiconductor substrate 10 is used, thereby increasing the output of the laser light.

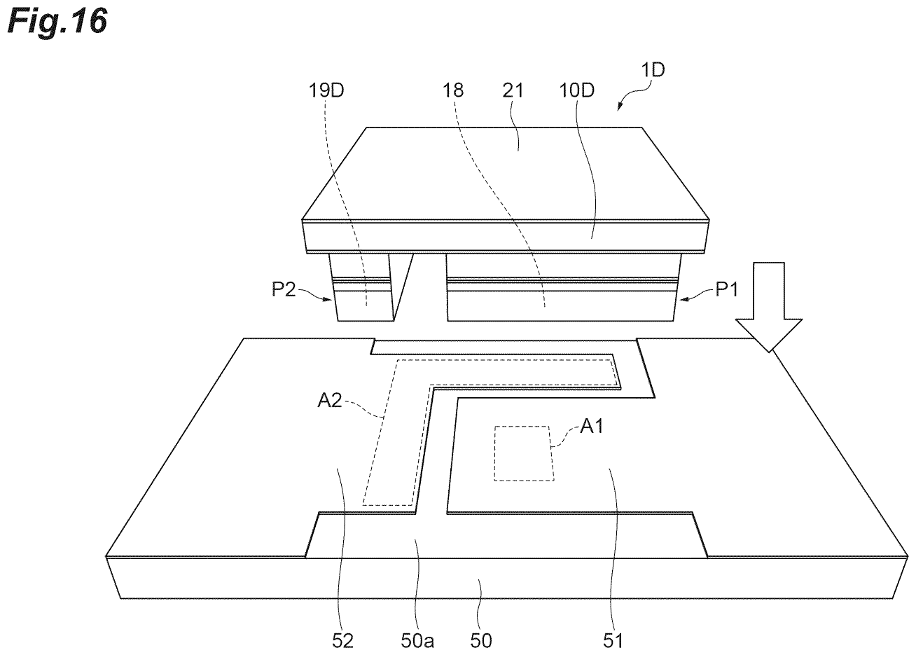

In addition, in the semiconductor laser device 1D, the electrode 18 is provided on the n-type contact layer 17 of the light-emitting portion P1, and the electrode 19D is provided so as to extend from the surface of the non-light-emitting portion P2 opposite to the semiconductor substrate 10D side to the surface 22a of the p-type contact layer 22. According to the above configuration, in the case where an n-type semiconductor substrate 10D is used, the electrode 19 for driving the semiconductor laser device 1D can be suitably disposed. More specifically, as shown in FIG. 13, the electrodes 18 and 19D are disposed so as to be spatially separated from each other across the groove G1 on substantially the same plane. As a result, as shown in FIG. 16, the semiconductor laser device 1D can be easily mounted on a wiring substrate 50 by so-called epi-side-down mounting. In the example of FIG. 16, the wiring substrate 50 is formed in a rectangular plate shape. The wiring substrate 50 has a surface 50a on which the semiconductor laser device 1D is disposed, and electrodes 51 (cathode electrode) and 52 (anode electrode) that are insulated from each other on the surface 50a. The electrode 51 has a region Al overlapping the electrode 18 on the light-emitting portion P1, and the electrode 52 has a region A2 overlapping the electrode 19D on the non-light-emitting portion P2. According to the semiconductor laser device 1D, the surface of the semiconductor multilayer structure 11D opposite to the semiconductor substrate 10D side can be easily mounted on the surface 50a of the wiring substrate 50 so that the electrodes 18 and 19D overlap the regions A1 and A2, respectively.

### Fifth Embodiment

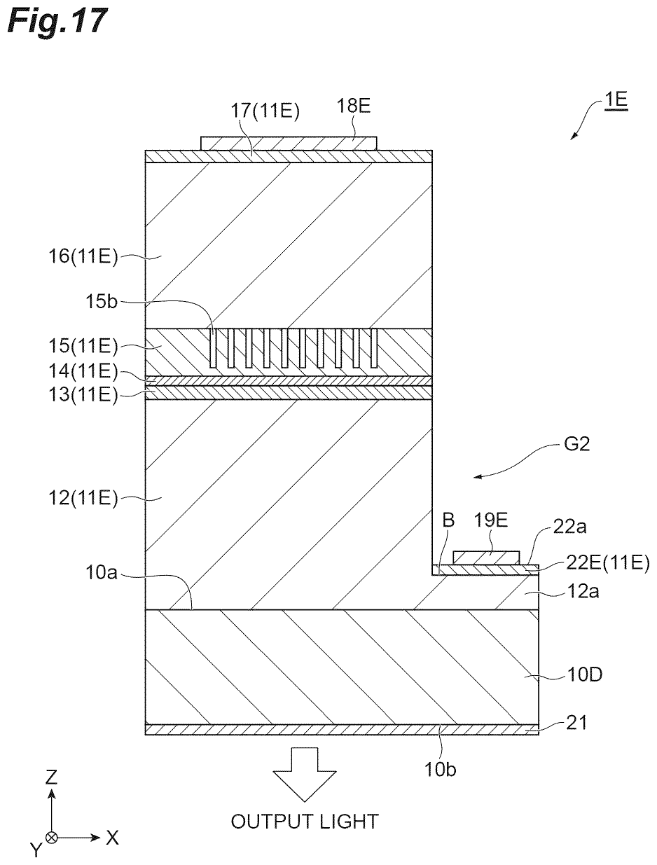

A semiconductor laser device 1E according to a fifth embodiment will be described with reference to FIG. 17. As shown in FIG. 17, the semiconductor laser device 1E mainly differs from the semiconductor laser device 1A in that it includes a semiconductor substrate 10D, a semiconductor multilayer structure 11E, and electrodes 18E and 19E instead of the semiconductor substrate 10, the semiconductor multilayer structure 11, and the electrodes 18 and 19. The semiconductor laser device 1E is configured as a surface-emitting laser diode similar to the semiconductor laser devices 1A and 1D. Note that, in the semiconductor laser device 1E, the insulating film 20 is not provided, but an insulating film similar to those in the semiconductor laser devices 1A and 1D may be provided.

The semiconductor multilayer structure 11E is provided with a groove G2 extending from a surface of the semiconductor multilayer structure 11E opposite to the semiconductor substrate 10D side to a position inside the p-type cladding layer 12 and spaced apart from the semiconductor substrate 10D. In the example of FIG. 17, the groove G2 is configured as a notch groove having a shape in which one edge of the semiconductor multilayer structure 11E in the X-axis direction is cut away along the Y-axis direction. Note that the groove G2 may also be provided along the edge of the semiconductor multilayer structure 11E in the Y-axis direction.

The thickness (length in the Z-axis direction) of the portion 12a of the p-type cladding layer 12 between the bottom B of the groove G2 and the main surface 10a of the semiconductor substrate 10D is smaller than the thickness of the portion of the p-type cladding layer 12 where the groove G2 is not formed (the portion corresponding to the light-emitting portion P1 of the semiconductor laser device 1D). In the semiconductor laser device 1E, the p-type contact layer 22E is disposed (stacked) inside the groove G2. In this embodiment, the p-type contact layer 22E is disposed on the upper surface of the portion 12a (i.e., on the bottom B of the groove G2). The electrode 18E is provided on the n-type contact layer 17, and the electrode 19E is provided on the surface 22a (the surface opposite to the bottom B side) of the p-type contact layer 22E.

The semiconductor laser device 1E can be manufactured, for example, as follows. First, the semiconductor multilayer structure 11E (in a state where the groove G2 is not yet formed) is formed on the semiconductor substrate 10D. Next, the groove G2 is formed in the semiconductor multilayer structure 11E by etching or the like so that the portion 12a of the p-type cladding layer 12 remains. Next, the p-type contact layer 22E is formed on the portion 12a. Next, the electrodes 18E and 19E and the antireflection film 21 are formed. In this way, the semiconductor laser device 1E having the structure shown in FIG. 17 is obtained.

According to the semiconductor laser device 1E, since it is not necessary to form the p-type contact layer 22 between the semiconductor substrate 10D and the p-type cladding layer 12 as in the structure of the semiconductor laser device 1D, it is possible to avoid the occurrence of absorption loss of the laser light in the p-type contact layer 22. As a result, the output of the laser light can be further increased.

### Sixth Embodiment

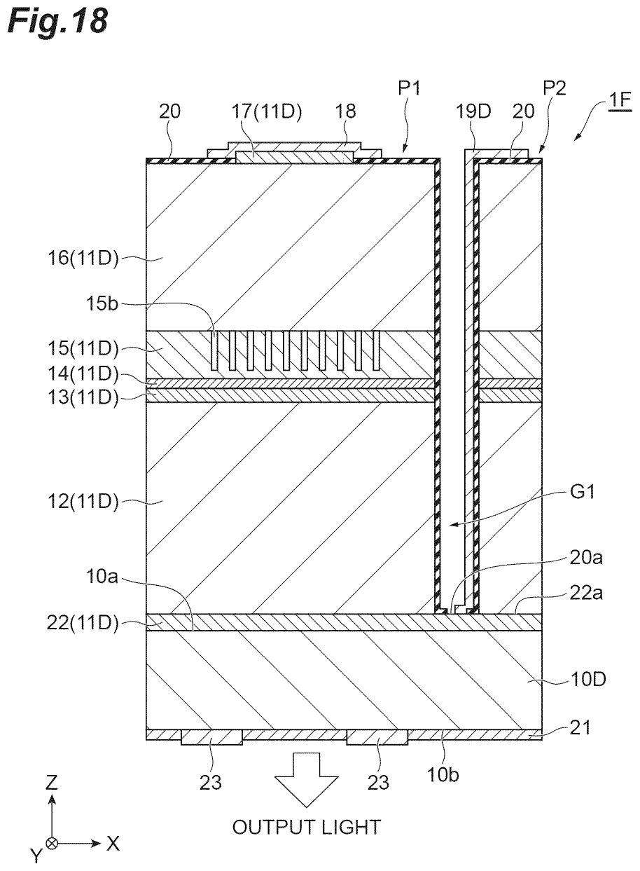

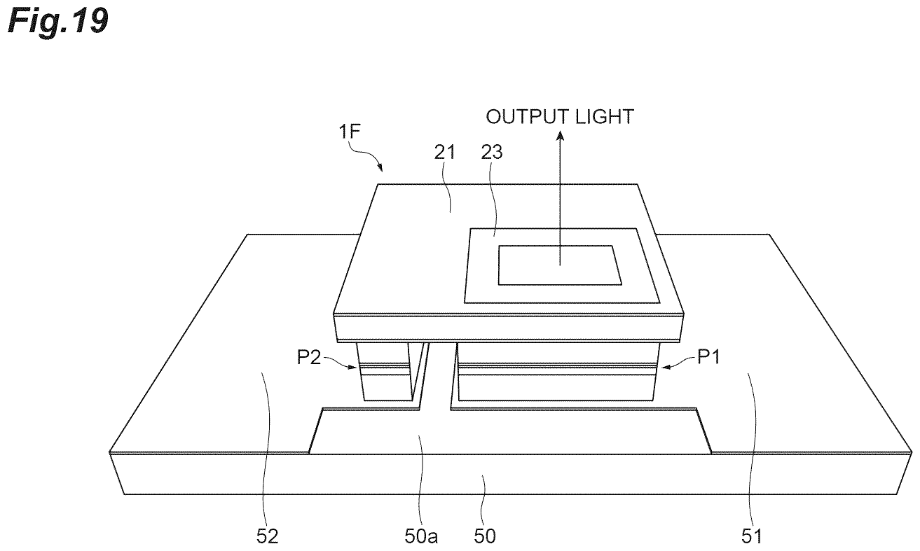

A semiconductor laser device 1F according to a sixth embodiment will be described with reference to FIGS. 18 and 19. As shown in FIGS. 18 and 19, the semiconductor laser device 1F mainly differs from the semiconductor laser device 1D in that, in addition to the electrodes 18 and 19D, it includes an electrode 23 (third electrode) formed on the back surface 10b of the semiconductor substrate 10D (the surface of the semiconductor substrate opposite to the semiconductor multilayer structure side), similar to the electrode 19 of the semiconductor laser device 1A.

In the semiconductor laser device 1F, the electrode 18 connected to the electrode 51 of the wiring substrate 50 functions as an emitter electrode, the electrode 19D connected to the electrode 52 of the wiring substrate 50 functions as a base electrode, and the electrode 23 functions as a collector electrode, so that the semiconductor laser device 1F can be operated as a transistor laser capable of high-speed operation. More specifically, by operating so that carriers injected from the emitter electrode (electrode 18) are extracted by the collector electrode (electrode 23), high-speed carrier supply to the active layer 14 can be realized. As a result, the semiconductor laser device 1F can function as a transistor laser capable of high-speed modulation.

As described above, embodiments and some modifications of the present disclosure have been described, but the present disclosure is not limited to the configurations shown in the above embodiments and modifications. The materials and shapes of each configuration are not limited to the specific materials and shapes described above, and various materials and shapes other than those described above can be adopted. In addition, some configurations included in the above embodiments and modifications may be omitted or changed as appropriate. For example, in the above embodiments, several characteristic configurations included in the semiconductor laser device and several effects exhibited by each configuration have been described, but the semiconductor laser device according to the present disclosure does not necessarily have to be configured to exhibit all the effects described in the above embodiments, and may be configured to exhibit only some of the effects described in the above embodiments. In the latter case, the semiconductor laser device only needs to include the configurations essential for exhibiting at least the relevant effects, and configurations not essential for exhibiting the relevant effects may be omitted or changed as appropriate. Note that, when focusing on a single effect, the configuration essential for exhibiting the effect should be reasonably understood based on common technical knowledge and the description of this specification, with reference to a person skilled in the art. Below, several specific modifications of the semiconductor laser device of the present disclosure will be exemplified, but it goes without saying that the modifications of the semiconductor laser device are not limited to the specific forms exemplified below.

For example, the fourth and fifth embodiments may be combined. That is, in the semiconductor laser device 1E of the fifth embodiment, a groove similar to the groove G1 of the fourth embodiment may be provided instead of the groove G2, and the light-emitting portion Pl and the non-light-emitting portion P2 may be provided. The electrode 19E may be formed so as to extend to the upper surface of the non-light-emitting portion P2. In this case, the effect of the fifth embodiment (i.e., the effect of being able to suppress optical absorption loss by not providing the p-type contact layer 22 between the semiconductor substrate 10D and the p-type cladding layer 12) can be obtained, as well as the effect of the fourth embodiment (i.e., the effect of facilitating epi-side-down mounting as shown in FIG. 16).

In addition, the electrode 23 of the sixth embodiment may be additionally provided in the semiconductor laser device 1E of the fifth embodiment. Even with such a configuration, the semiconductor laser device 1E can be operated as a transistor laser, similarly to the semiconductor laser device 1F of the sixth embodiment.

In the semiconductor laser device 1D of the fourth embodiment, the shape of the groove G1 does not necessarily have to be formed in an L-shape along two adjacent sides of the light-emitting portion P1. For example, as viewed from the Z-axis direction, two independent (separated) grooves may be formed along two sides of the light-emitting portion P1 facing each other (for example, two sides facing each other in the X-axis direction or two sides facing each other in the Y-axis direction). Alternatively, an I-shaped groove along only one side of the light-emitting portion P1 may be formed, or a U-shaped groove along three sides of the light-emitting portion P1 may be formed, or a rectangular ring-shaped groove along all four sides of the light-emitting portion P1 may be formed. Thus, the shape of the groove G1 is not limited to a specific shape. However, by forming the groove G1 in an L-shape as in this embodiment, it is possible to balance the area of the light-emitting portion P1 and the area of the mounting surface of the non-light-emitting portion P2 (i.e., the contact area between the electrode 19D and the electrode 52). Note that, from the viewpoint of suitably injecting current into the light-emitting portion P1, the shape of the groove G1 is preferably, in order, a rectangular ring, U-shape, L-shape, and I-shape. That is, from the above viewpoint, it is most preferable for the groove G1 to be a rectangular ring that allows current injection from all four sides of the light-emitting portion P1, next preferable is a U-shape that allows current injection from three sides, next preferable is an L-shape that allows current injection from two sides, and next preferable is an I-shape that allows current injection from one side. On the other hand, from the viewpoint of reducing the mounting area (i.e., the width of the semiconductor laser device 1D in the X-axis and Y-axis directions), the shape of the groove G1 is preferably, in order, I-shape, L-shape, U-shape, and rectangular ring. That is, when the groove G1 is formed as a rectangular ring surrounding all four sides of the light-emitting portion P1, the mounting area is the largest, whereas when the groove G1 is formed as an I-shape along only one side of the light-emitting portion P1, the mounting area can be reduced compared to the case where the groove G1 is formed as a rectangular ring, by the amount that the portions along the remaining three sides are reduced.

In addition, the semiconductor laser devices 1D to 1F may be configured as edge-emitting laser diodes by including an n-type guide layer 15B similar to that of the semiconductor laser device 1B.

### REFERENCE SIGNS LIST

1A, 1B, 1C, 1D, 1E, 1F: Semiconductor laser device
10, 10D: Semiconductor substrate
11, 11B, 11C, 11D, 11E: Semiconductor multilayer structure
12: p-type cladding layer
13: non-doped guide layer
14: active layer
15, 15B, 15C: n-type guide layer
15a: base layer
15b: different refractive index region (fine structure portion)
15c: diffraction grating (fine structure portion)
17: n-type contact layer
18, 18E: electrode (first electrode)
19, 19D, 19E: electrode (second electrode)
22, 22E: p-type contact layer
22a: surface (first surface)
23: electrode (third electrode)
G1, G2: groove
P1: light-emitting portion (first portion)
P2: non-light-emitting portion (second portion)

1. A semiconductor laser device comprising:
a semiconductor substrate; and
a semiconductor multilayer structure formed on the semiconductor substrate,
wherein the semiconductor multilayer structure includes:
an active layer;
a p-type cladding layer disposed between the semiconductor substrate and the active layer;
a non-doped guide layer disposed between the p-type cladding layer and the active layer;
an n-type guide layer disposed on a side of the active layer opposite to a side where the non-doped guide layer is located with respect to the active layer; and
an n-type cladding layer disposed on a side of the n-type guide layer opposite to a side where the active layer is located with respect to the n-type guide layer,
wherein Zn is doped in the p-type cladding layer,
wherein the non-doped guide layer is formed of InAlₓGa₁₋ₓAs (0<x≤1), and
wherein a thickness of the n-type guide layer in a stacking direction of the semiconductor multilayer structure is greater than a thickness of the non-doped guide layer in the stacking direction.

2. The semiconductor laser device according to claim 1,
wherein the semiconductor substrate is p-type.

3. The semiconductor laser device according to claim 2,
wherein the semiconductor multilayer structure further includes an n-type contact layer disposed on a side of the n-type cladding layer opposite to a side where the n-type guide layer is located with respect to the n-type cladding layer,
wherein the semiconductor laser device further comprises:
a first electrode provided on the n-type contact layer, and
a second electrode provided on a surface of the semiconductor substrate opposite to a side where the semiconductor multilayer structure is located.

4. The semiconductor laser device according to claim 1,
wherein the semiconductor substrate is n-type, and
wherein the semiconductor multilayer structure includes a p-type contact layer provided in contact with the p-type cladding layer.

5. The semiconductor laser device according to claim 4,
wherein the p-type contact layer is disposed between the semiconductor substrate and the p-type cladding layer,
wherein the semiconductor multilayer structure is provided with a groove extending from a surface of the semiconductor multilayer structure opposite to a side where the semiconductor substrate is located to a first surface of the p-type contact layer opposite to a side where the semiconductor substrate is located, and separating the semiconductor multilayer structure into a first portion and a second portion,
wherein the first portion is provided with an n-type contact layer disposed on a side of the n-type cladding layer opposite to a side where the n-type guide layer is located with respect to the n-type cladding layer,
wherein the semiconductor laser device further comprises:
a first electrode provided on the n-type contact layer, and
a second electrode provided so as to extend from a surface of the second portion opposite to a side where the semiconductor substrate is located to the first surface.

6. The semiconductor laser device according to claim 4,
wherein the semiconductor multilayer structure further comprises an n-type contact layer disposed on a side of the n-type cladding layer opposite to a side where the n-type guide layer is located with respect to the n-type cladding layer,
wherein the semiconductor multilayer structure is provided with a groove extending from a surface of the semiconductor multilayer structure opposite to a side where the semiconductor substrate is located to a position inside the p-type cladding layer and spaced apart from the semiconductor substrate,
wherein the p-type contact layer is disposed inside the groove,
wherein the semiconductor laser device further comprises:
a first electrode provided on the n-type contact layer, and
a second electrode provided on the p-type contact layer.

7. The semiconductor laser device according to claim 5,
further comprising a third electrode provided on a surface of the semiconductor substrate opposite to a side where the semiconductor multilayer structure is located.

8. The semiconductor laser device according to claim 1,
wherein Si is doped in the n-type guide layer and the n-type cladding layer.

9. The semiconductor laser device according to claim 1,
wherein a thickness of the n-type guide layer in the stacking direction is 2 μm or less.

10. The semiconductor laser device according to claim 1,
wherein a thickness of the non-doped guide layer in the stacking direction is 30 nm to 150 nm.

11. The semiconductor laser device according to claim 1,
wherein the n-type guide layer is provided with a fine structure portion having a fine concave-convex structure.

12. The semiconductor laser device according to claim 11,
wherein the n-type guide layer includes:
a base layer having a first refractive index; and
a plurality of different refractive index regions having a second refractive index different from the first refractive index,
wherein the fine structure portion is constituted by the plurality of different refractive index regions arranged two-dimensionally as viewed from the stacking direction.

13. The semiconductor laser device according to claim 11,
wherein the fine structure portion has a diffraction grating distributed along a resonance direction of the active layer perpendicular to the stacking direction.

14. The semiconductor laser device according to claim 11,
wherein a thickness of the n-type guide layer in the stacking direction is 1.5 times or more a thickness of the non-doped guide layer in the stacking direction.
